(19) United States
(12) Patent Application Publication
(10) Pub. No.: US 2012/0152595 A1
(43) Pub. Date: Jun. 21, 2012

(54) Multilayer printed circuit board and method of manufacturing the same

(75) Inventor: John Su Kyon, Changwon-si (KR)

(73) Assignee: SAMSUNG ELECTRO-MECHANICS CO., LTD., Suwon (KR)

(21) Appl. No.: 13/373,296

(22) Filed: Nov. 10, 2011

(30) Foreign Application Priority Data
Dec. 21, 2010 (KR) 10-2010-0131444

(51) Int. Cl. H05K 1/02; H05K 3/10

(52) U.S. Cl. 174/251; 29/846

(57) ABSTRACT

The present invention provides a method of manufacturing a multilayer printed circuit board including: forming a first printed circuit on a base substrate; applying a first insulator on a portion of the first printed circuit; forming a second printed circuit on the first insulator and a connection pattern of the first printed circuit; and applying a second insulator on the base substrate except the second printed circuit. According to the present invention, it is possible to simultaneously electrically connect multilayer printed circuits without a via hole.

### CROSS-REFERENCE TO RELATED APPLICATIONS

Claim and incorporate by reference domestic priority application and foreign priority application as follows:

### Cross Reference to Related Application

This application claims the benefit under 35 U.S.C. Section 119 of Korean Patent Application Serial No. 10-2010-0131444, entitled filed Dec. 21, 2010, which is hereby incorporated by reference in its entirety into this application.

### BACKGROUND OF THE INVENTION

1. Field of the Invention

The present invention relates to a multilayer printed circuit board and a method of manufacturing the same, and more particularly, to a multilayer printed circuit board and a method of manufacturing the same capable of forming multilayer printed circuits.

2. Description of the Related Art

In recent times, miniaturization and technology integration of electronic devices and products have been steadily developed due to advance of the electronic devices and products. In addition to this, various changes in a manufacturing process of a printed circuit board (PCB) used in the electronic devices and products are also needed in response to miniaturization and technology integration.

A technical direction for a method of manufacturing a PCB has been developed from a single-sided PCB to a double-sided PCB at an early stage and to a multilayer PCB again. Especially, recently, in manufacturing the multilayer PCB, a manufacturing method, which is called a build-up method, is being developed.

A manufacturing process of a multilayer PCB in accordance with the prior art forms a via hole in an interlayer insulator to electrically connect each layer having a printed circuit with a pattern and electroplates an inner wall of the via hole or fills the via hole with metal.

However, since the above-described multilayer PCB can perform interlayer electrical connection only through the via hole, there is a limitation on circuit design.

And there is a problem of an increase in size of the multilayer PCB.

### SUMMARY OF THE INVENTION

The present invention has been invented in order to overcome the above-described problems and it is, therefore, an object of the present invention to provide a multilayer printed circuit board capable of simultaneously electrically connecting multilayer printed circuits without a via hole by applying an insulator on an overlapped portion of a plurality of printed circuits, and a method of manufacturing the same.

In accordance with one aspect of the present invention to achieve the object, there is provided a method of manufacturing a multilayer printed circuit board including the steps of: forming a first printed circuit on a base substrate; applying a first insulator on a portion of the first printed circuit; forming a second printed circuit on the first insulator and a connection pattern of the first printed circuit; and applying a second insulator on the base substrate except the second printed circuit.

Here, the connection pattern of the first printed circuit may be electrically connected to the second printed circuit.

And the first printed circuit may include a disconnection pattern on which the first insulator is applied; and the connection pattern having an exposed upper surface on which the second printed circuit is formed.

Moreover, the step of forming the first printed circuit to the step of applying the second insulator may be repeated according to the number of layers of the multilayer printed circuit board.

Further, the step of forming the first printed circuit may form the first printed circuit by plating metal on the base substrate and etching the plated metal.

At this time, the first insulator may be an insulating ink.

In addition, the step of applying the first insulator may apply the first insulator by printing the insulating ink on a portion of the first printed circuit.

Meanwhile, in accordance with another aspect of the present invention to achieve the object, there is provided a multilayer printed circuit board including: a base substrate; a first printed circuit formed on the base substrate; a first insulator applied on a portion of the first printed circuit; a second printed circuit formed on the first insulator and a connection pattern of the first printed circuit; and a second insulator applied on the base substrate except the second printed circuit.

Here, the connection pattern of the first printed circuit may be electrically connected to the second printed circuit.

And the first printed circuit may include a disconnection pattern on which the first insulator is applied; and the connection pattern having an exposed upper surface on which the second printed circuit is formed.

Further, the first printed circuit, the first insulator, the second printed circuit, and the second insulator may be formed in plural number according to the number of layers of the multilayer printed circuit board.

At this time, the first insulator may be an insulating ink.

And a portion of the first printed circuit is applied by printing the insulating ink.

### BRIEF DESCRIPTION OF THE DRAWINGS

These and/or other aspects and advantages of the present general inventive concept will become apparent and more readily appreciated from the following description of the embodiments, taken in conjunction with the accompanying drawings of which:

FIG. 1 is a cross sectional view of a multilayer printed circuit board in accordance with an embodiment of the present invention;

FIG. 2 is an operation flow chart showing a process of manufacturing a multilayer printed circuit board in accordance with an embodiment of the present invention;

FIGS. 3 to 10 are cross sectional views showing the process of manufacturing a multilayer printed circuit board in accordance with an embodiment of the present invention;

FIG. 11a is a circuit pattern diagram of a multilayer printed circuit board in accordance with the prior art; and

FIG. 11b is a circuit pattern diagram of the multilayer printed circuit board in accordance with an embodiment of the present invention.

### DETAILED DESCRIPTION OF THE PREFERABLE EMBODIMENTS

The terms or words used in the present specification and claims should not be interpreted as being limited to typical or dictionary meanings, but should be interpreted as having meanings and concepts relevant to the technical spirit of the present invention based on the rule according to which an inventor can appropriately define the concept of the term to describe his/her own invention in the best manner.

Therefore, configurations shown in embodiments and the drawings of the present invention rather are examples of the most exemplary embodiment and do not represent all of the technical spirit of the invention. Thus, it will be understood that various equivalents and modifications that replace the configurations are possible when filing the present application.

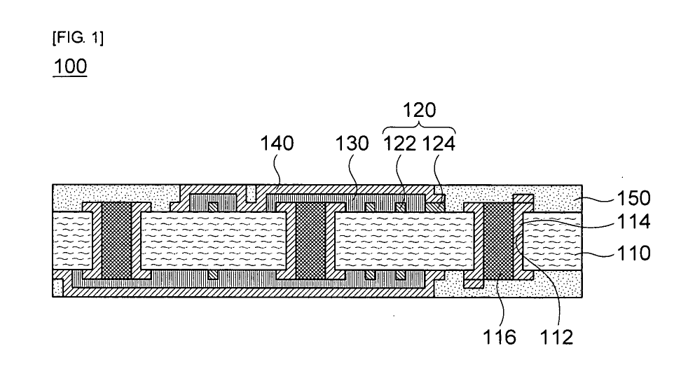

FIG. 1 is a cross sectional view of a multilayer printed circuit board in accordance with an embodiment of the present invention.

As shown in FIG. 1, a multilayer printed circuit board 100 includes a base substrate 110, a first printed circuit 120, a first insulator 130, a second printed circuit 140, and a second insulator 150.

The base substrate 110 is a raw material of the multilayer printed circuit board 100 and may be composed of a copper clad laminate (CCL) or a glass fiber substrate impregnated with a thermosetting resin composition (glass fiber reinforced prepreg impregnated with a thermosetting resin composition).

At this time, the CCL includes a single-sided CCL formed by sequentially depositing an insulating layer and a copper layer and a double-sided CCL formed by sequentially depositing a lower copper layer, an insulating layer, and an upper copper layer.

A via hole 112 is formed in the base substrate 110, and metal 114 is plated on an inner peripheral surface of the via hole 112. Further, an insulating material 116 is filled in the via hole 112.

The first printed circuit 120 is formed by plating metal on the base substrate 110 and etching the plated metal. That is, in order to form the first printed circuit 120, after plating metal on the base substrate 110, an etching resist is selectively applied on a portion where a circuit should be left, that is, a circuit pattern portion. And the first printed circuit 120 is formed by removing the etching resist after performing an etching process.

Besides the above-described plating and etching method, the first printed circuit 120 may be formed by printing a circuit pattern on the base substrate 110 with a paste composition including conductive particles and heating the paste composition to be imidized.

And the first printed circuit 120 includes a disconnection pattern 122 and a connection pattern 124.

Among them, the disconnection pattern 122 is a portion of the first printed circuit 120 on which the first insulator 130 is applied, and the connection pattern 124 is the remaining portion of the first printed circuit 120 having an exposed upper surface on which the second printed circuit 140 is formed.

The first insulator 130 is applied on the disconnection pattern 122, that is, a portion of the first printed circuit 120.

More specifically, the disconnection pattern 122 of the first printed circuit 120 is a portion that should not be electrically connected to the second printed circuit 140, and the first insulator 130 is applied on an overlapped portion of the disconnection pattern 122 of the first printed circuit 120 and the second printed circuit 140 so that the disconnection pattern 122 of the first printed circuit 120 and the second printed circuit 140 are not electrically overlapped with each other.

The first insulator 130 may be composed of an insulating ink and applied on the disconnection pattern 122 of the first printed circuit 120 by printing the insulating ink on the disconnection pattern 122 of the first printed circuit 120, that is, a portion of the first printed circuit 120. Further, the first insulator 130 may be composed of various insulating materials besides the insulating ink and applied on the disconnection pattern 122 of the first printed circuit 120 by laminating or filling the insulating material.

The second printed circuit 140 is formed on the first insulator 130 and the connection pattern 124 of the first printed circuit 120.

Like the above method of forming the first printed circuit 120, the second printed circuit 140 may be formed by plating metal on one or both surfaces of the base substrate 110 and etching the plated metal or printing a circuit pattern on the base substrate 110 with a paste composition including conductive particles and heating the paste composition to be imidized.

Like this, the first printed circuit 120 and the second printed circuit 140 are electrically connected to each other by forming the second printed circuit 140 on the connection pattern 124 of the first printed circuit 120.

The second insulator 150 is applied on the base substrate 110 except the second printed circuit 140.

Like the first insulator 130, this second insulator 150 may be applied by printing an insulating ink or filling or laminating an insulating material.

As described above, one layer (first layer) of the multilayer printed circuit board may be completed by applying the second insulator 150 on the base substrate 110 except the second printed circuit 140.

Meanwhile, even though the multilayer printed circuit board may be described to have the first layer formed on one surface of the base substrate 110, the multilayer printed circuit board may be formed on both surfaces of the base substrate 110, and the first printed circuit 120, the first insulator 130, the second printed circuit 140, and the second insulator 150 may be formed in plural number according to the number of layers of the multilayer printed circuit board.

The multilayer printed circuit board having a plurality of layers will be described below.

Hereinafter, a process of manufacturing a multilayer printed circuit board in accordance with an embodiment of the present invention will be described.

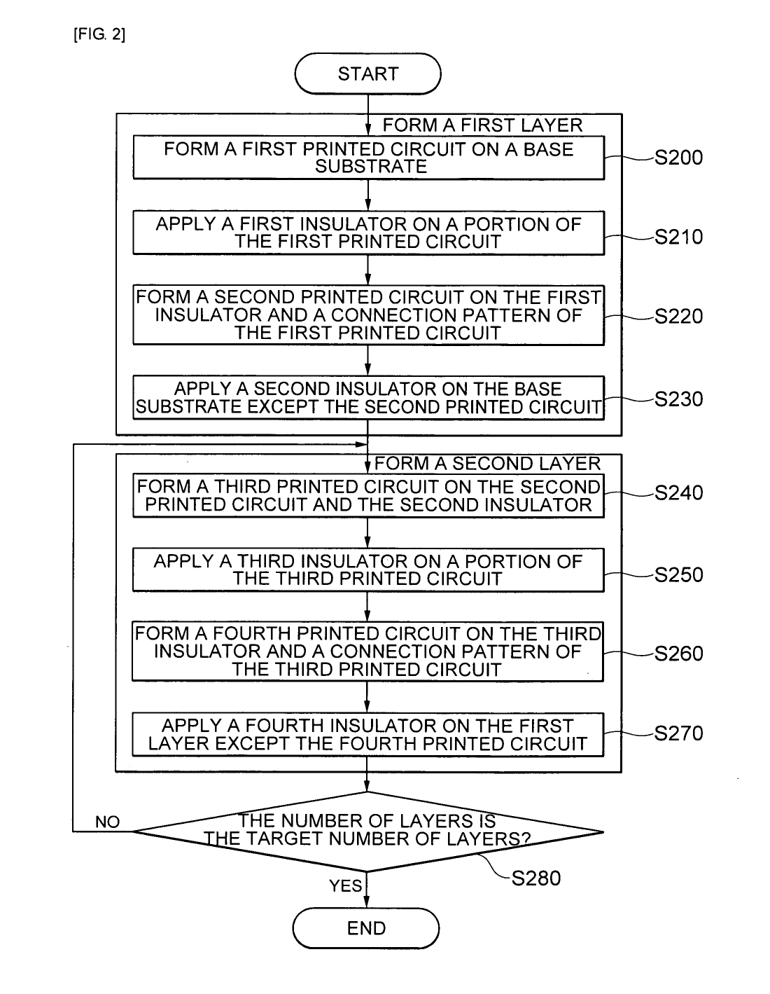

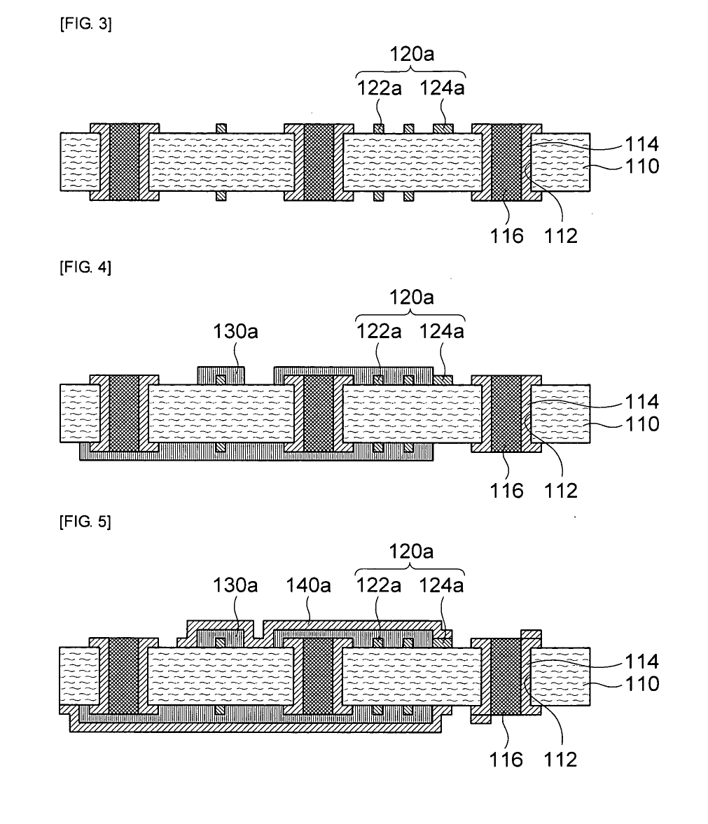

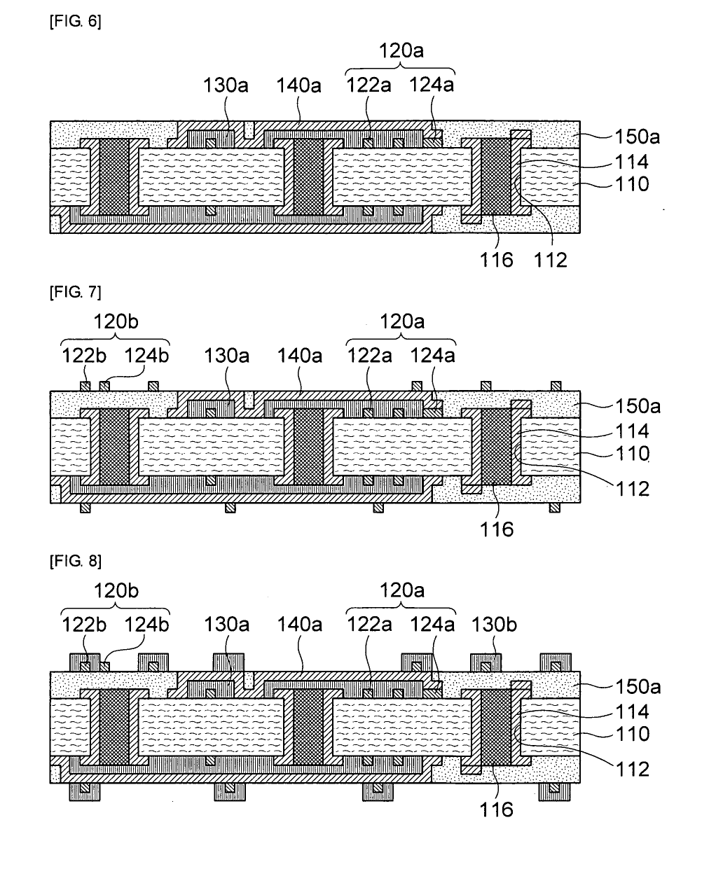

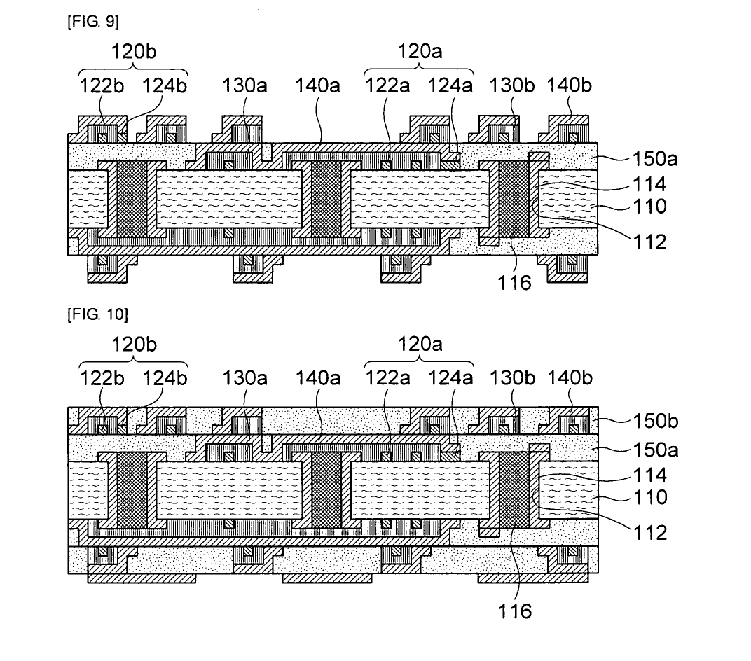

FIG. 2 is an operation flow chart showing a process of manufacturing a multilayer printed circuit board in accordance with an embodiment of the present invention, and FIGS. 3 to 10 are cross sectional views showing the process of manufacturing a multilayer printed circuit board in accordance with an embodiment of the present invention.

Referring to FIG. 2 and FIGS. 3 to 10, a first printed circuit 120a is formed on a base substrate 110 (S200).

Here, the first printed circuit 120a is formed by plating metal on the base substrate 110 and etching the plated metal. That is, in order to form the first printed circuit 120a, after plating the base substrate 110, an etching resist is selectively applied on a portion where a circuit should be left, that is, a circuit pattern portion. And the first printed circuit 120a is formed by removing the etching resist after performing an etching process.

Alternately, the first printed circuit 120a may be formed by printing a circuit pattern on the base substrate 110 with a paste composition including conductive particles and heating the paste composition to be imidized.

Besides this, the circuit may be formed by using various methods.

Moreover, the first printed circuit 120a includes a disconnection pattern 122a and a connection pattern 124a. Among them, the disconnection pattern 122a is a portion of the first printed circuit 120a on which a first insulator 130a is applied, and the connection pattern 124a is the remaining portion of the first printed circuit 120a having an exposed upper surface on which a second printed circuit 140a is formed.

And the first insulator 130a is applied on a portion of the first printed circuit 120a.

Here, a portion of the first printed circuit 120a, that is, the disconnection pattern 122a, is a portion other than a portion that should be electrically connected to the second printed circuit 140a.

More specifically, the first insulator 130a is applied on an overlapped portion of the disconnection pattern 122a of the first printed circuit 120a and the second printed circuit 140a so that the disconnection pattern 122a of the first printed circuit 120a and the second printed circuit 140a are not electrically overlapped with each other on one layer.

The first insulator 130a may be composed of an insulating ink and applied on the disconnection pattern 122a of the first printed circuit 120a by printing the insulating ink on the disconnection pattern 122a, that is, a portion of the first printed circuit 120a. Further, the first insulator 130a may be composed of various insulating materials besides the insulating ink and applied on the disconnection pattern 122a of the first printed circuit 120a by laminating or filling the insulating material.

Next, the second printed circuit 140a is formed on the first insulator 130a and the connection pattern 124a of the first printed circuit 120a (S220).

Like the method of forming the first printed circuit 120a, the second printed circuit 140a may be formed by plating metal on the base substrate 110 and etching the plated metal or printing a circuit pattern on the base substrate 110 with a paste composition including conductive particles and heating the paste composition to be imidized.

Like this, the first printed circuit 120a and the second printed circuit 140a are electrically connected to each other by forming the second printed circuit 140a on the connection pattern 124a of the first printed circuit 120a.

Next, a first layer is formed by applying a second insulator 150a on the base substrate 110 except the second printed circuit 140a (S230). Like the first insulator 130a, this second insulator 150a may be applied by printing the insulating ink or filling or laminating the insulating material.

As described above, after forming the first layer, a third printed circuit 120b is formed on the first layer (S240), and a third insulator 130b is applied on a portion of the third printed circuit 120b (S250).

Next, a second layer is formed by forming a fourth printed circuit 140b on the third insulator 130b and a connection pattern 124b of the third printed circuit 120b (S260) and applying a fourth insulator 150b on the first layer, that is, the second printed circuit 140a and the second insulator 150a, except the fourth printed circuit 140b (S270).

And it is determined whether the number of layers reaches the target number of layers of the multilayer printed circuit board (S280), and the steps S240 to S270 are repeatedly performed until the number of layers reaches the target number of layers of the multilayer printed circuit board.

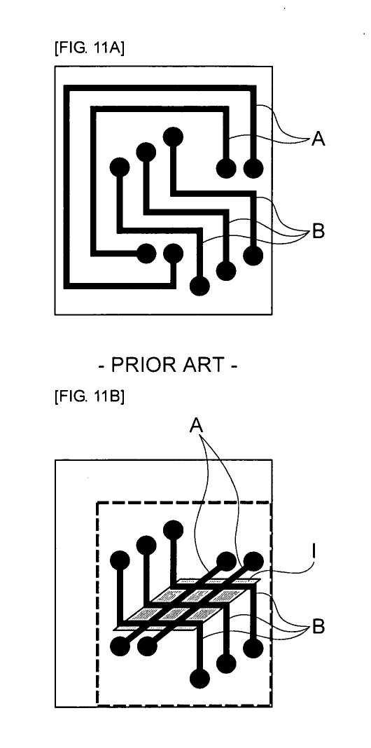

FIG. 11a is a circuit pattern diagram of a multilayer printed circuit board in accordance with the prior art, and FIG. 11b is a circuit pattern diagram of the multilayer printed circuit board in accordance with an embodiment of the present invention.

As shown in FIG. 11a, according to the prior art, in order to implement a plurality of printed circuits, that is, a first printed circuit A and a second printed circuit B, on one layer, since the first and second printed circuits A and B should be designed two-dimensionally to be formed in parallel on the same layer so that they are not electrically overlapped with each other, there was problems such as limitation on circuit design and an increase in size of the printed circuit board.

In an embodiment of the present invention for solving these problems, as shown in FIG. 11b, since an insulator I is applied on an overlapped portion of a first printed circuit A and a second printed circuit B, the first and second printed circuits A and B can be designed three-dimensionally and in various forms.

Due to this, electrical connection is possible by forming the printed circuits in the directions of Z axis as well as X and Y axes, and interlayer electrical connection is possible even in a structure without a hole or via.

Further, it is possible to reduce manufacturing cost by reducing a size of the multilayer printed circuit board.

As described above, according to a multilayer printed circuit board and a method of manufacturing the same in accordance with an embodiment of the present invention, it is possible to simultaneously electrically connect multilayer printed circuits without a via hole by applying an insulator on an overlapped portion of a plurality of printed circuits.

Due to this, it is possible to improve reliability of electrical connection of the multilayer printed circuit board, and it is possible to implement high integration circuit design by designing the printed circuits having various structures.

While the invention has been described in detail with reference to preferred embodiments thereof, it will be appreciated by those skilled in the art that various changes and modifications may be made in these embodiments without departing from the scope of the invention.

What is claimed is:

1. A method of manufacturing a multilayer printed circuit board comprising:
forming a first printed circuit on a base substrate;
applying a first insulator on a portion of the first printed circuit;
forming a second printed circuit on the first insulator and a connection pattern of the first printed circuit; and
applying a second insulator on the base substrate except the second printed circuit.

2. The method of manufacturing a multilayer printed circuit board according to claim 1, wherein the connection pattern of the first printed circuit is electrically connected to the second printed circuit.

3. The method of manufacturing a multilayer printed circuit according to claim 1, wherein the first printed circuit comprises:
a disconnection pattern on which the first insulator is applied; and
the connection pattern having an exposed upper surface on which the second printed circuit is formed.

4. The method of manufacturing a multilayer printed circuit according to claim 1, wherein forming the first printed circuit to applying the second insulator are repeated according to the number of layers of the multilayer printed circuit board.

5. The method of manufacturing a multilayer printed circuit according to claim 1, wherein forming the first printed circuit forms the first printed circuit by plating metal on the base substrate and etching the plated metal.

6. The method of manufacturing a multilayer printed circuit according to claim 1, wherein the first insulator is an insulating ink.

7. The method of manufacturing a multilayer printed circuit according to claim 6, wherein applying the first insulator applies the first insulator by printing the insulating ink on a portion of the first printed circuit.

8. A multilayer printed circuit board comprising:
a base substrate;
a first printed circuit formed on the base substrate;
a first insulator applied on a portion of the first printed circuit;
a second printed circuit formed on the first insulator and a connection pattern of the first printed circuit; and
a second insulator applied on the base substrate except the base substrate.

9. The multilayer printed circuit board according to claim 8, wherein the connection pattern of the first printed circuit is electrically connected to the second printed circuit.

10. The multilayer printed circuit board according to claim 8, wherein the first printed circuit comprises:
a disconnection pattern on which the first insulator is applied; and
the connection pattern having an exposed upper surface on which the second printed circuit is formed.

11. The multilayer printed circuit board according to claim 8, wherein the first printed circuit, the first insulator, the second printed circuit, and the second insulator are formed in plural number according to the number of layers of the multilayer printed circuit board.

12. The multilayer printed circuit board according to claim 8, wherein the first insulator is an insulating ink.

13. The multilayer printed circuit board according to claim 12, wherein a portion of the first printed circuit is applied by printing the insulating ink.
